(19) United States
(12) Patent Application Publication
(10) Pub. No.: US 2010/0129938 A1
(43) Pub. Date: May 27, 2010

(54) SEMICONDUCTOR DEVICE AND METHOD OF MANUFACTURING THE SAME

(75) Inventors: Yoshinori Kumura, Yokohama-shi (JP); Yoshiro Shimojo, Yokohama-shi (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: KABUSHIKI KAISHA TOSHIBA, Tokyo (JP)

(21) Appl. No.: 12/692,712

(22) Filed: Jan. 25, 2010

Related U.S. Application Data
(62) Division of application No. 12/233,987, filed on Sep. 19, 2008.

(30) Foreign Application Priority Data
Sep. 20, 2007 (JP) 2007-243904

(51) Int. Cl. H01L 21/77

(52) U.S. Cl. 438/3; 438/681; 257/E21.598

(57) ABSTRACT

A semiconductor device includes: a semiconductor substrate and a transistor formed on the semiconductor substrate. The semiconductor device also includes: a first interlayer insulation film formed on the semiconductor substrate including the upper portion of the transistor, a first contact formed to be connected through the first interlayer insulation film to the transistor, a ferroelectric capacitor formed to be connected to the first contact, a second interlayer insulation film formed on the first interlayer insulation film, and a second contact formed to connect the ferroelectric capacitor to a wiring through the second interlayer insulation film. The contact surfaces between the second contact and the ferroelectric capacitor have the same planar shape.

### CROSS REFERENCE TO RELATED APPLICATIONS

This application is a divisional application of U.S. application Ser. No. 12/233,987, filed Sep. 19, 2008 which is based on and claims the benefit of priority from prior Japanese Patent Application No. 2007-243904, filed on Sep. 20, 2007, the entire contents of each of which are incorporated herein by reference.

### BACKGROUND OF THE INVENTION

1. Field of the Invention

The present invention relates to a semiconductor device and a method of manufacturing the same, and in particular, to a semiconductor device using ferroelectric capacitors and a method of manufacturing the same.

2. Description of the Related Art

Some configurations are known for forming a semiconductor storage device where a capacitor is formed with a ferroelectric film sandwiched between electrodes and the resulting ferroelectric capacitor is used as a storage element. Such a ferroelectric capacitor maintains its polarization when voltage application is stopped after writing information, which may provide a non-volatile semiconductor storage device. In forming such a semiconductor storage device, it is necessary to form a contact on the upper electrode of the capacitor that provides an electrical connection between a ferroelectric capacitor and a wiring. As the integration density of devices increases, the size of ferroelectric capacitors becomes smaller, which results in a larger aspect ratio (the ratio of the contact depth to the contact diameter) in each contact formed on the ferroelectric capacitor. Forming contacts with a high aspect ratio requires super-resolving masks, super-resolution exposure, RIE (Reactive Ion Etching) process of minute contacts, etc., which would lead to difficulties in the manufacturing process of semiconductor devices.

On the contrary, other configurations are known for achieving a reduced aspect ratio by providing a hydrogen diffusion barrier film on the upper electrode and forming an aperture in the hydrogen diffusion barrier film (see, Japanese Patent Laid-Open No. 2005-101052). However, since the aperture diameter becomes relatively small in this configuration, problems arise due to poor contact between a wiring contact and an upper electrode.

### SUMMARY OF THE INVENTION

One aspect of the present invention provides a semiconductor device comprising: a semiconductor substrate; a transistor formed on the semiconductor substrate; a first interlayer insulation film formed on the semiconductor substrate including the upper portion of the transistor; a first contact formed to be connected through the first interlayer insulation film to the transistor; a ferroelectric capacitor formed to be connected to the first contact; a second interlayer insulation film formed on the first interlayer insulation film; and a second contact formed to connect the ferroelectric capacitor to a wiring through the second interlayer insulation film, wherein the contact surfaces between the second contact and the ferroelectric capacitor have the same planar shape.

Another aspect of the present invention provides a method of manufacturing a semiconductor device, the method comprising: forming a transistor on a semiconductor substrate; forming a first interlayer insulation film on the semiconductor substrate including the upper portion of the transistor; forming a first contact to be connected through the first interlayer insulation film to the transistor; depositing a lower electrode on the first contact; depositing a ferroelectric film on the lower electrode; depositing an upper electrode on the ferroelectric film; depositing mask material on the upper electrode; forming a ferroelectric capacitor including the upper electrode, the ferroelectric film, and the lower electrode, through patterning of the mask material, the upper electrode, the ferroelectric film, and the lower electrode such that the mask material remains on the upper electrode; forming a first hydrogen diffusion barrier film on the first interlayer insulation film and the ferroelectric capacitor; forming a second interlayer insulation film on the first hydrogen diffusion barrier film; removing the second interlayer insulation film and the first hydrogen diffusion barrier film to expose the mask material; removing the mask material; and forming a second contact through deposition of conductive material on the ferroelectric capacitor with the mask material removed therefrom.

### BRIEF DESCRIPTION OF THE DRAWINGS

FIG. 1 is a cross-sectional view of a semiconductor device according to a first embodiment of the present invention;

FIG. 2 is a process diagram illustrating a method of manufacturing the semiconductor device according to the first embodiment of the present invention;

FIG. 3 is a process diagram illustrating the method of manufacturing the semiconductor device according to the first embodiment of the present invention;

FIG. 4 is a process diagram illustrating the method of manufacturing the semiconductor device according to the first embodiment of the present invention;

FIG. 5 is a process diagram illustrating the method of manufacturing the semiconductor device according to the first embodiment of the present invention;

FIG. 6 is a process diagram illustrating the method of manufacturing the semiconductor device according to the first embodiment of the present invention;

FIG. 7 is a process diagram illustrating the method of manufacturing the semiconductor device according to the first embodiment of the present invention;

FIG. 8 is a cross-sectional view of a semiconductor device according to a second embodiment of the present invention;

FIG. 9 is a process diagram illustrating a method of manufacturing the semiconductor device according to the second embodiment of the present invention;

FIG. 10 is a process diagram illustrating the method of manufacturing the semiconductor device according to the second embodiment of the present invention;

FIG. 11 is a cross-sectional view of a semiconductor device according to another embodiment of the present invention; and

FIG. 12 is a cross-sectional view of a semiconductor device according to still another embodiment of the present invention.

### DETAILED DESCRIPTION OF THE EMBODIMENTS

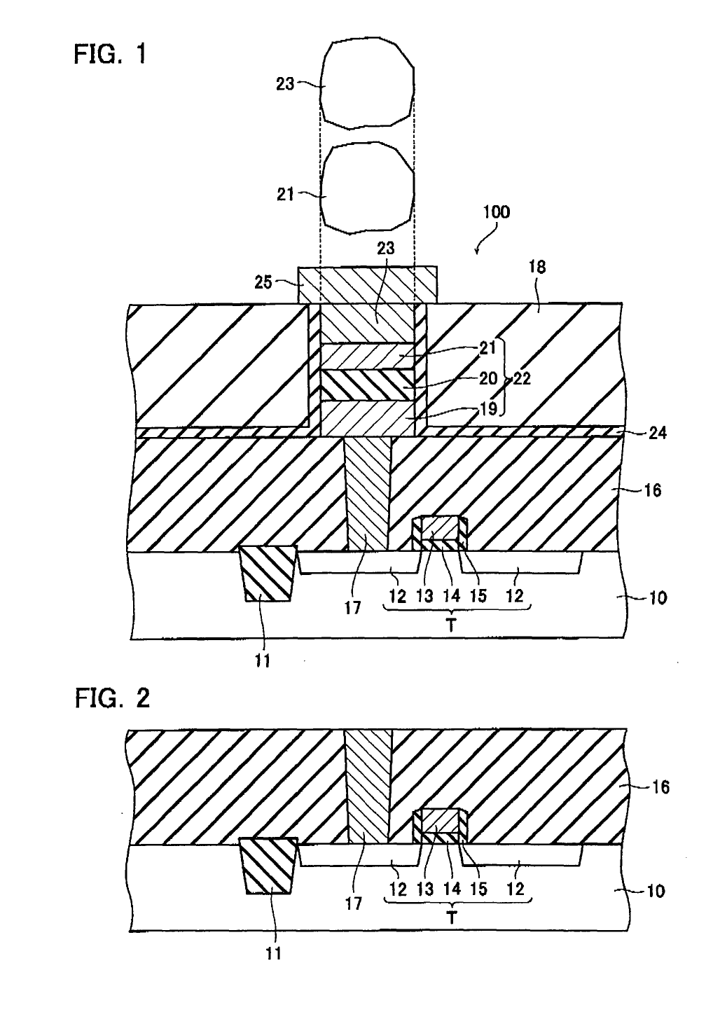

A first embodiment of the present invention will now be described below with reference to the accompanying drawings. FIG. 1 is a cross-sectional view of a semiconductor device 100 according to the first embodiment.

The semiconductor device 100 of this embodiment is formed on a silicon substrate 10. The region where the semiconductor device 100 is formed is isolated from other semiconductor devices on the silicon substrate 10 by a device isolation region 11, which is formed on the silicon substrate 10 through STI (Shallow Trench Isolation). The isolated silicon substrate 10 has a pair of source/drain diffusion layers 12 formed thereon, in which impurities are diffused. A gate electrode 13 is formed on an area of the silicon substrate 10 between the source/drain diffusion layers 12 via a gate insulation film 14. In addition, sidewall insulation films 15 are formed on sidewalls of the gate electrode 13. The pair of source/drain diffusion layers 12, the gate electrode 13, the gate insulation film 14, and the sidewall insulation films 15 together configure a transistor T. An interlayer insulation film 16 that consists of, e.g., BPSG (Boron Phosphorous Silicate Glass) is also formed on the silicon substrate 10 including the upper portion of the gate electrode 13. The interlayer insulation film 16 may be of P-TEOS (Plasma-Tetra Ethoxy Silane). A contact hole is formed through the interlayer insulation film 16 and into one of the source/drain diffusion layers 12. The contact hole is filled with, e.g., tungsten (W), thereby forming a contact 17. The material for forming the contact 17 may be polysilicon with doped impurities.

The interlayer insulation film 16 has an interlayer insulation film 18 formed thereon that consists of, e.g., a silicon oxide (SiO₂) film. The interlayer insulation film 18 may be formed by, e.g., a P-TEOS, O₃-TEOS, SOG, or Low-k film (such as a fluorine-doped silicon oxide (SiOF) or carbon-doped silicon oxide (SiOC) film). A ferroelectric capacitor 22 and a wiring contact 23 are formed within the interlayer insulation film 18. A lower electrode 19 that consists of e.g., platinum (Pt) is formed in the interlayer insulation film 18 so as to contact the upper surface of the contact 17. The lower electrode 19 is electrically connected to the source/drain diffusion layers 12 of the transistor T via the contact 17. The lower electrode 19 has a ferroelectric film 20 formed thereon including PZT (Pb(Zrₓ, Ti₁₋ₓ)O₃), etc. The ferroelectric film 20 may include material such as SBT (SrBi₂Ta₂O₉). Further, the ferroelectric film 20 has an upper electrode 21 formed thereon that consists of, e.g., platinum (Pt). The lower electrode 19 and the upper electrode 21 may be formed with material including any of the following: iridium (Ir), iridium oxide (IrO₂), SRO (SrRuO₃), ruthenium (Ru), ruthenium oxide (RuO₂), etc. The lower electrode 19, the ferroelectric film 20, and the upper electrode 21 together configure the ferroelectric capacitor 22.

The upper electrode 21 has the wiring contact 23 formed thereon that consists of, e.g., tungsten (W). The wiring contact 23 may be formed with material including any of the following: aluminum (Al), titanium nitride (TiN), copper (Cu), titanium (Ti), tantalum (Ta), tantalum nitride (TaN), etc. The upper electrode 21 and a wiring 25 are electrically connected through the wiring contact 23. In this embodiment, the ferroelectric capacitor 22 has the same planar shape as that of the wiring contact 23. In addition, the respective side surfaces of the ferroelectric capacitor 22 and the wiring contact 23 conform to each other, and thus are formed as a continuous surface.

A hydrogen diffusion barrier film 24 that consists of, e.g., aluminum oxide (Al₂O₃) is formed at the boundary between the interlayer insulation film 16 and the interlayer insulation film 18. The hydrogen diffusion barrier film 24 is also formed in a continuous manner on the respective side surfaces of the ferroelectric capacitor 22 and the wiring contact 23 as a continuous film. The wiring contact 23 has a wiring 25 formed thereon that consists of, e.g., copper (Cu). The wiring 25 is connected to a semiconductor device (not illustrated) formed on the silicon substrate 10. The wiring 25 may be formed with material including any of the following: tungsten (W), aluminum (Al), titanium nitride (TiN), tantalum (Ta), tantalum nitride (TaN), etc.

For the semiconductor device 100 of this embodiment, the contact surfaces between the ferroelectric capacitor 22 and the wiring contact 23 have the same planar shape and the respective side surfaces of the wiring contact 23 and the ferroelectric capacitor 22 conform to each other. Therefore, it is ensured that the upper electrode 21 is connected to the wiring contact 23 and contact failure can be prevented therebetween, thereby reducing contact resistance. In addition, since the hydrogen diffusion barrier film 24 is also formed on the side surfaces of the wiring contact 23, any diffusion of hydrogen into the ferroelectric film 20 can be prevented in forming process of the semiconductor device 100 and thus no degradation occurs in characteristics of the ferroelectric capacitor 22.

As illustrated in FIG. 1, the contact surfaces between the ferroelectric capacitor 22 and the wiring contact 23 may have any shape, not limited to a square, circular, or other shape, as long as they have the same planar shape.

A method of manufacturing the semiconductor device 100 according to the first embodiment will now be described below. FIGS. 2 through 7 are process diagrams illustrating a method of manufacturing the semiconductor device 100 of the first embodiment.

A device isolation region 11 is selectively formed on the silicon substrate 10 through STI for forming a trench in the silicon substrate 10 and filling the trench with an insulation film. Then, the gate electrode 13 is formed on the silicon substrate 10 via the gate insulation film 14 and the sidewall insulation films 15. Impurities are diffused on the silicon substrate 10 using the gate electrode 13 as a mask to form a pair of source/drain diffusion layers 12 in such a way that the gate electrode 13 is sandwiched between the source/drain diffusion layers 12. Then, the interlayer insulation film 16 that consists of, e.g., BPSG is deposited on the silicon substrate 10 including the upper portion of the gate electrode 13. The upper surface of the interlayer insulation film 16 is then planarized through, e.g., CMP (Chemical Mechanical Polishing). Thereafter, a contact hole is formed through the interlayer insulation film 16 and into one of the pair of source/drain diffusion layers 12 on the silicon substrate 10. The contact 17 is formed by, for example, filling the contact hole with tungsten (W) and then planarizing it (see FIG. 2).

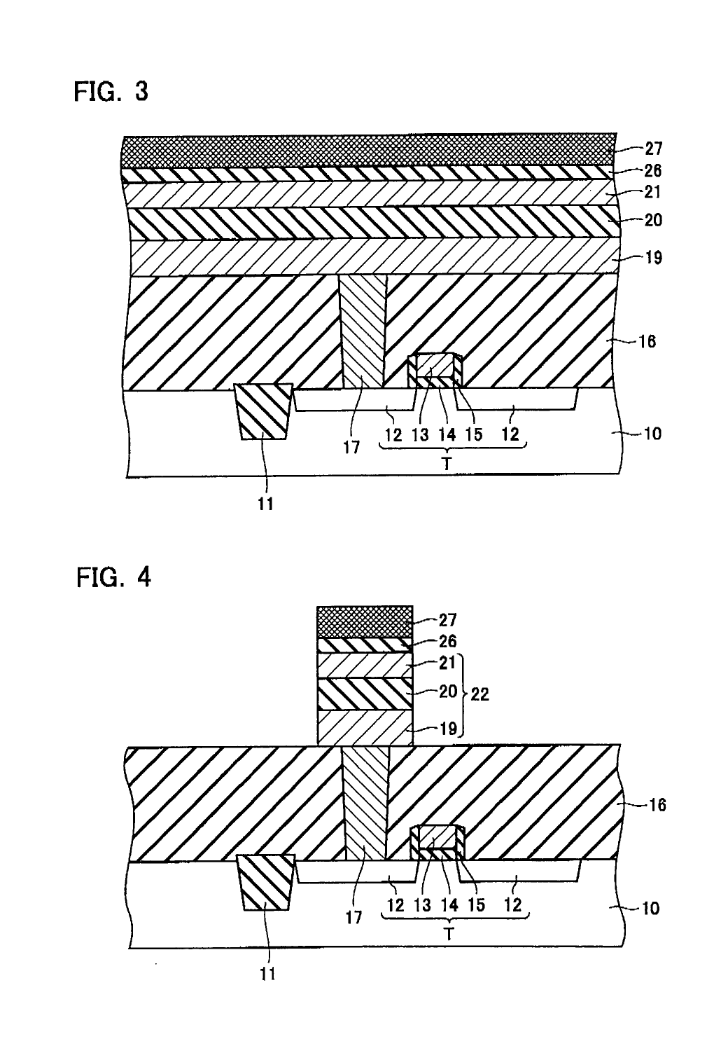

Then, a platinum (Pt) film of the lower electrode 19, a PZT film of the ferroelectric film 20, and a platinum (Pt) film of the upper electrode 21 are deposited in turn on the interlayer insulation film 16 including the upper portion of the contact 17. In addition, a second hydrogen diffusion barrier film 26 that consists of, e.g., aluminum oxide (Al₂O₃) is deposited on the upper electrode 21. Further, mask material 27 that consists of, e.g., a silicon nitride (SiN) film is deposited thereon as a hard mask for processing the lower electrode 19, the ferroelectric film 20, the upper electrode 21, and the second hydrogen diffusion barrier film 26. The second hydrogen diffusion barrier film 26 is provided for protecting the ferroelectric film 20 from hydrogen produced in forming the mask material 27 (see FIG. 3).

Through patterning on the deposited film, the ferroelectric capacitor 22 is formed that includes the lower electrode 19, the ferroelectric film 20, and the upper electrode 21. In this embodiment, the second hydrogen diffusion barrier film 26 and the mask material 27 remains on the patterned ferroelectric capacitor 22. The remaining mask material 27 has a film thickness of, for example, 100 to 200 nm (see FIG. 4).

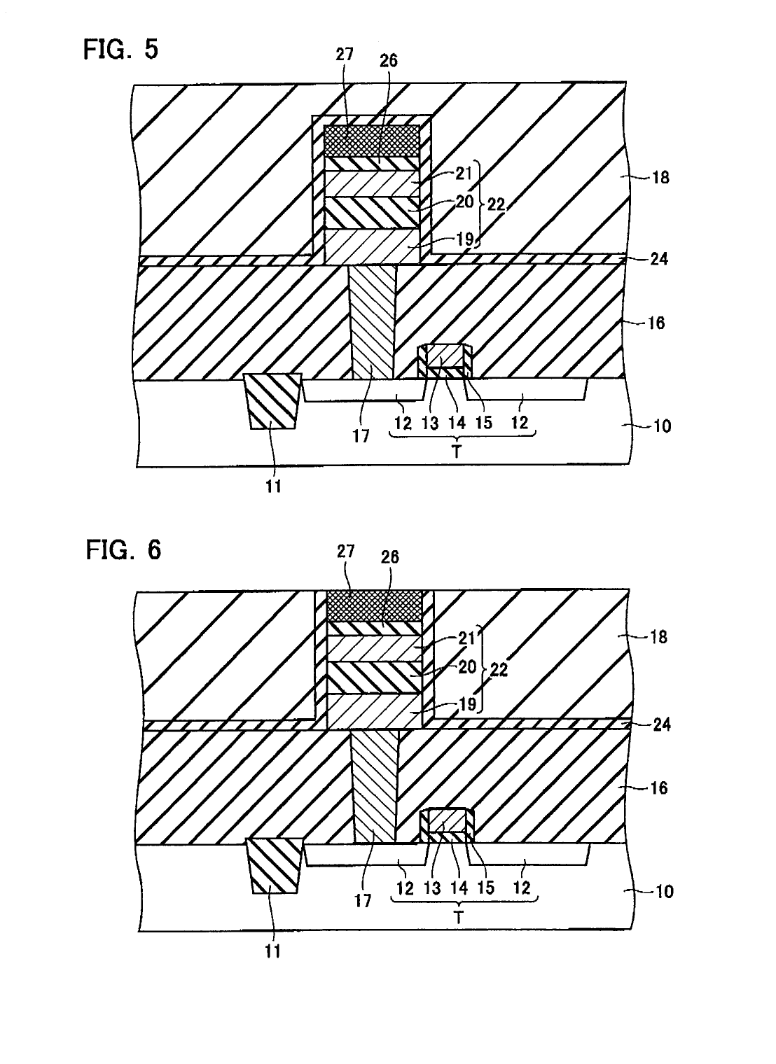

The hydrogen diffusion barrier film 24 that consists of aluminum oxide (Al₂O₃) is formed on the interlayer insulation film 16 including the upper portion of the ferroelectric capacitor 22, using, for example, an ALD method (Atomic Layer Deposition) or sputter method. The interlayer insulation film 18 that consists of, e.g., a silicon oxide (SiO₂) film is formed on the hydrogen diffusion barrier film 24 (see FIG. 5).

The interlayer insulation film 18 and the hydrogen diffusion barrier film 24 are planarized using CMP or RIE. In this embodiment, the mask material 27 on the ferroelectric capacitor 22 is processed to be exposed on the surface (see FIG. 6).

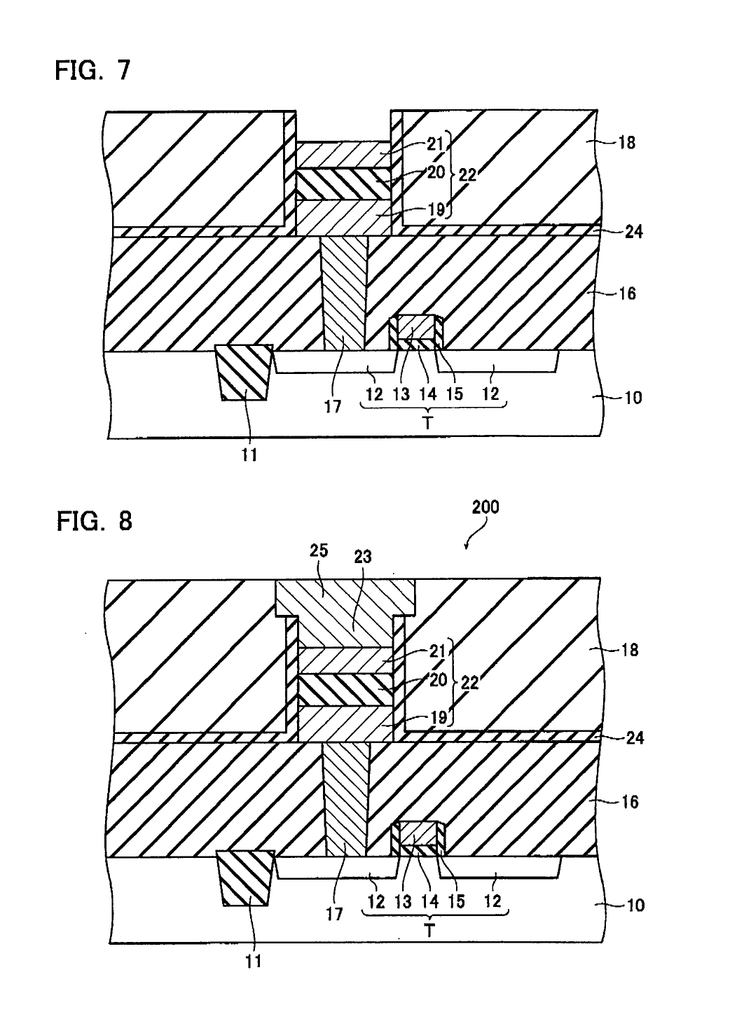

Then, such process is performed whereby the mask material 27 has a high selectivity with respect to the interlayer insulation film 18 and the hydrogen diffusion barrier films 24, 26, e.g., such wet etching is performed using phosphoric acid at normal temperature. While the mask material 27 of a silicon nitride (SiN) film is etched by the phosphoric acid treatment, the interlayer insulation film 18 of a silicon oxide (SiO₂) film and the hydrogen diffusion barrier films 24, 26 of aluminum oxide (Al₂O₃) remains with little effect of etching. As a result, patterns for forming a wiring contact are opened by self-alignment. In addition to wet etching using phosphoric acid, such RIE may be used as etching that involves a processing selectivity for a silicon nitride (SiN) film and a silicon oxide (SiO₂) film. Thereafter, the second hydrogen diffusion barrier film 26 exposed on the upper electrode 21 is removed by RIE (see FIG. 7).

Tungsten (W) is deposited on the interlayer insulation film 18 through, e.g., MOCVD (Metal-Organic Chemical Vapor Deposition) so that the aperture is filled therewith that is formed by removing the mask material 27 and the second hydrogen dif fusion barrier film 26. The deposition method may include sputtering, plating, sputter-reflow, etc. Thereafter, tungsten (W) is planarized to expose the upper surface of the interlayer insulation film 18 to form the wiring contact 23. Wiring material that consists of, e.g., copper (Cu) is deposited on the wiring contact 23 and the interlayer insulation film 18 and then patterning is performed thereon by, e.g., RIE process to form the wiring 25. In this way, the semiconductor device 100 of this embodiment is formed as illustrated in FIG. 1.

As can be seen from the above, in the method of manufacturing the semiconductor device 100 of this embodiment, the mask material 27 remains when forming the ferroelectric capacitor 22. Such etching is performed whereby the mask material 27 has a high selectivity with respect to the interlayer insulation film 18 and the hydrogen diffusion barrier films 24, 26, and then the mask material 27 is removed that remains on the ferroelectric capacitor 22. By filling the aperture from which the mask material 27 is removed with conductor material, the wiring contact 23 may be formed that has a contact surface with the same planar shape as that of the ferroelectric capacitor 22 and that has the side surfaces conforming to those of the ferroelectric capacitor 22. Since this process is self-alignment process, no alignment error occurs between the ferroelectric capacitor 22 and the wiring contact 23.

A second embodiment of the present invention will now be described below with reference to the accompanying drawings. FIG. 8 is a cross-sectional view of a semiconductor device 200 according to the second embodiment. For the semiconductor device 200 of this embodiment, the same reference numerals represent the same components as the first embodiment and description thereof will be omitted.

The semiconductor device 200 of this embodiment is different from the semiconductor device of the first embodiment in that the wiring contact 23 and the wiring 25 on the upper electrode 21 of the ferroelectric capacitor 22 are formed through damascene process. The wiring contact 23 and the wiring 25, each of which is connected to the upper electrode 21, are integrally formed to be embedded within the interlayer insulation film 18 using the same material. Also in this embodiment, the contact surfaces between the ferroelectric capacitor 22 and the wiring contact 23 have the same planar shape. In addition, the respective side surfaces of the ferroelectric capacitor 22 and the wiring contact 23 conform to each other.

Also for the semiconductor device 200 of this embodiment, the contact surfaces between the ferroelectric capacitor 22 and the wiring contact 23 have the same planar shape and the respective side surfaces of the wiring contact 23 and the ferroelectric capacitor 22 conform to each other. Therefore, it is ensured that the upper electrode 21 is connected to the wiring contact 23 and contact failure can be prevented therebetween, thereby reducing contact resistance. In addition, since the hydrogen diffusion barrier film 24 is also formed on the side surfaces of the wiring contact 23, any diffusion of hydrogen into the ferroelectric film 20 can be prevented in forming process of the semiconductor device 200 and thus no degradation occurs in characteristics of the ferroelectric capacitor 22.

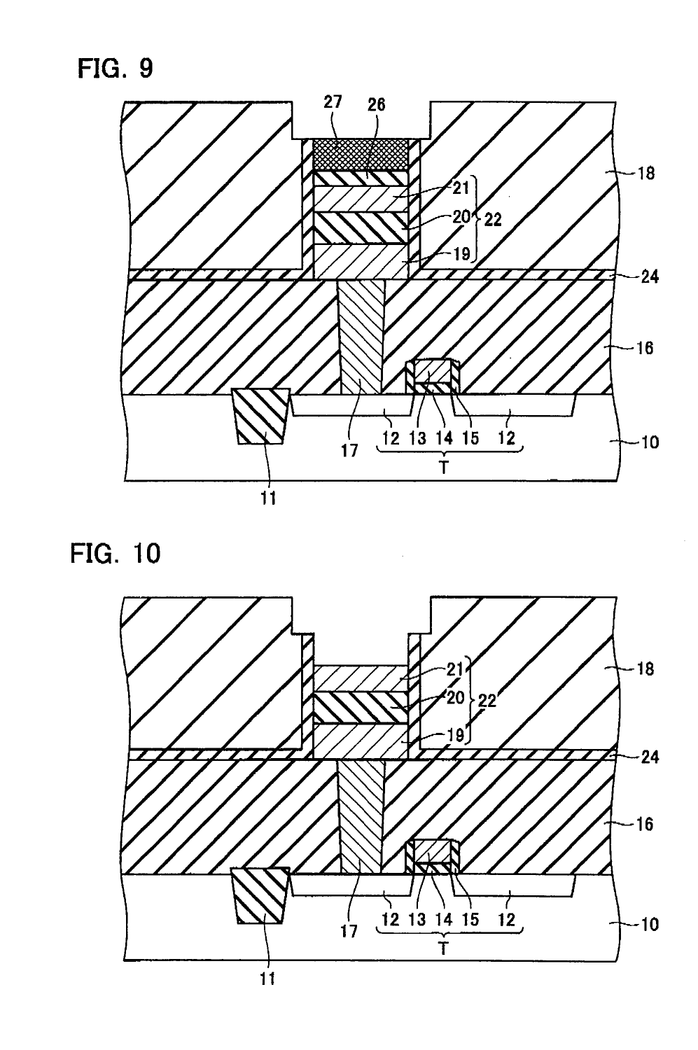

A method of manufacturing the semiconductor device 200 according to the second embodiment will now be described below. FIGS. 9 and 10 are process diagrams illustrating a method of manufacturing the semiconductor device 200 of the second embodiment. The method of manufacturing the semiconductor device 200 of the second embodiment is similar to the method of manufacturing the semiconductor device of the first embodiment until the steps of forming the interlayer insulation film 18 illustrated in FIGS. 2 through 5. The method of manufacturing the semiconductor device 200 of this embodiment is different from the method of manufacturing the semiconductor device 100 of the first embodiment in that the wiring contact 23 and the wiring 25 are formed through damascene process.

After forming the interlayer insulation film 18, the interlayer insulation film 18 and the hydrogen diffusion barrier film 24 are etched by RIE. At this moment, the etching is performed in such a way that patterns for the wiring 25 are formed in the interlayer insulation film 18. This etching continues on the ferroelectric capacitor 22 until the hydrogen diffusion barrier film 24 is removed to expose the mask material 27 (see FIG. 9).

Then, such process is performed whereby the mask material 27 has a high selectivity with respect to the interlayer insulation film 18 and the hydrogen diffusion barrier films 22, 24, e.g., a phosphoric acid treatment is performed at normal temperature. While the mask material 27 of a silicon nitride (SiN) film is etched by the phosphoric acid treatment, the interlayer insulation film 18 of a silicon oxide (SiO₂) film and the hydrogen diffusion barrier films 22, 24 of aluminum oxide (Al₂O₃) remains with little effect of etching. As a result, patterns for forming the wiring contact 23 are opened by self-alignment. Thereafter, the second hydrogen diffusion barrier film 26 is etched and removed by RIE (see FIG. 10).

Tungsten (W) is deposited on the interlayer insulation film 18 through, e.g., MOCVD so that an aperture for the wiring contact 23 and a trench for the wiring 25 that is formed in the interlayer insulation film 18 are filled therewith. The deposition method may include sputtering, plating, sputter-reflow, etc. Thereafter, tungsten (W) is planarized to expose the upper surface of the interlayer insulation film 18 to form the wiring contact 23 and the wiring 25. In this way, the semiconductor device 200 of this embodiment is formed as illustrated in FIG. 8.

As can be seen from the above, in the method of manufacturing the semiconductor device 200 of this embodiment, the mask material 27 also remains when forming the ferroelectric capacitor 22. Such etching is performed whereby the mask material 27 has a high selectivity with respect to the interlayer insulation film 18 and the hydrogen diffusion barrier films 24, 26, and then the mask material 27 is removed that remains on the ferroelectric capacitor 22. By filling the aperture from which the mask material 27 is removed with conductor material, the wiring contact 23 may be formed that has a contact surface with the same planar shape as that of the ferroelectric capacitor 22 and that has the side surfaces conforming to those of the ferroelectric capacitor 22. Since this process is self-alignment process, no alignment error occurs between the ferroelectric capacitor 22 and the wiring contact 23. Further, in the method of manufacturing the semiconductor device 200 of this embodiment, the wiring contact 23 and the wiring 25 may be formed at the same time through damascene process. Consequently, RIE process is not required for forming the wiring 25, which results in more simple manufacturing process.

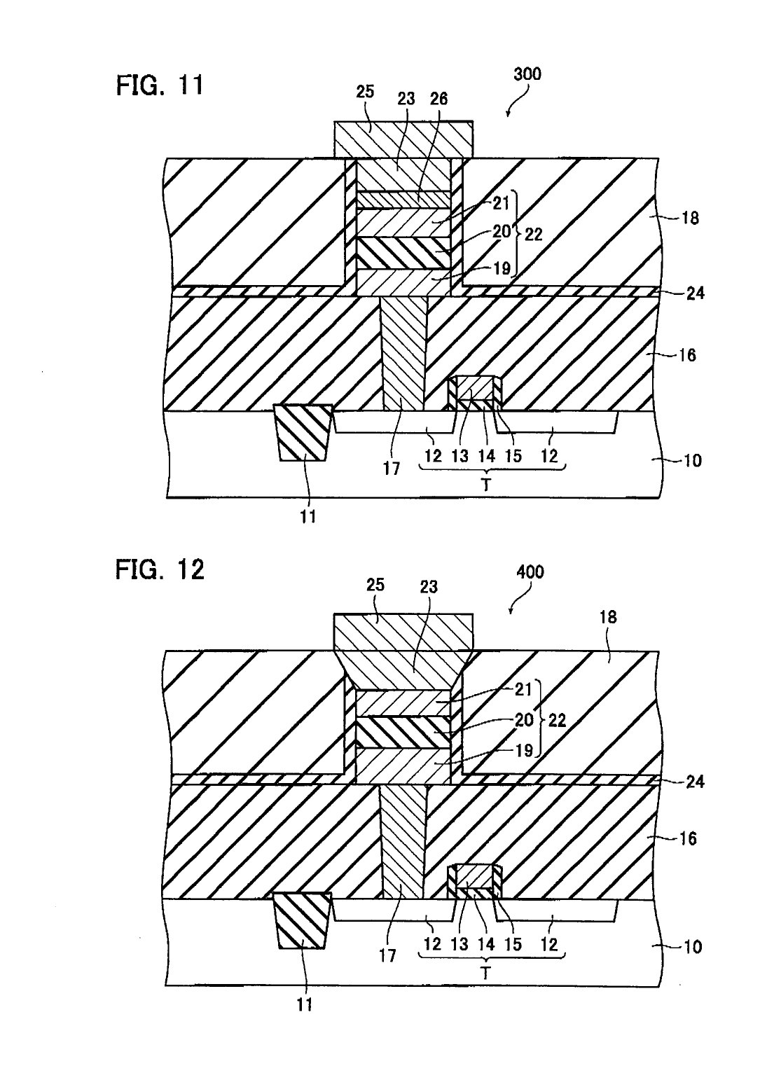

Although embodiments of the present invention have been described, the present invention is not intended to be limited to the disclosed embodiments and various other changes, additions or the like may be made thereto without departing from the spirit of the invention. For example, in the embodiments described above, the second hydrogen diffusion barrier film 26 is formed on the upper electrode 21 and is also removed by etching after removing the mask material 27. However, the second hydrogen diffusion barrier film 26 may be configured with conductive material, e.g., titanium aluminum nitride (TiAlN) and manufactured without being removed by etching (see FIG. 11). In this case, a semiconductor device 300 illustrated in FIG. 11 has the second hydrogen diffusion barrier film 26 on the upper electrode 21 of the ferroelectric capacitor 22. In each step after forming the ferroelectric capacitor 22, any diffusion of hydrogen into the ferroelectric film 20, as well as degradation in characteristics of the ferroelectric capacitor 22 can be prevented in more reliable manner.

In addition, the embodiments of the present invention have been described herein in the context of the respective side surfaces of the ferroelectric capacitor 22 and the wiring contact 23 conforming to each other. However, as illustrated in FIG. 12, the respective side surfaces of the ferroelectric capacitor 22 and the wiring contact 23 need not necessarily conform to each other, as long as the contact surfaces between the ferroelectric capacitor 22 and the wiring contact 23 have the same planar shape. A semiconductor device 400 illustrated in FIG. 12 also has the same planar shape in the contact surfaces between the ferroelectric capacitor 22 and the wiring contact 23. Accordingly, it is ensured that the upper electrode 21 is connected to the wiring contact 23 and contact failure can be prevented therebetween, thereby reducing contact resistance.

What is claimed is:

1. A method of manufacturing a semiconductor device, the method comprising:
forming a transistor on a semiconductor substrate;
forming a first interlayer insulation film on the semiconductor substrate including the upper portion of the transistor;
forming a first contact to be connected through the first interlayer insulation film to the transistor;
depositing a lower electrode on the first contact;
depositing a ferroelectric film on the lower electrode;
depositing an upper electrode on the ferroelectric film;
depositing mask material on the upper electrode;
forming a ferroelectric capacitor including the upper electrode, the ferroelectric film, and the lower electrode, through patterning of the mask material, the upper electrode, the ferroelectric film, and the lower electrode such that the mask material remains on the upper electrode;
forming a first hydrogen diffusion barrier film on the first interlayer insulation film and the ferroelectric capacitor;
forming a second interlayer insulation film on the first hydrogen diffusion barrier film;
removing the second interlayer insulation film and the first hydrogen diffusion barrier film to expose the mask material;
removing the mask material; and
forming a second contact through deposition of conductive material on the ferroelectric capacitor with the mask material removed therefrom.

2. The method of manufacturing the semiconductor device according to claim 1, wherein
the removing the mask material is such etching process whereby the mask material has a high selectivity with respect to the second interlayer insulation film and the first hydrogen diffusion barrier film.

3. The method of manufacturing the semiconductor device according to claim 1, wherein
the removing the mask material is wet etching using phosphoric acid at normal temperature.

4. The method of manufacturing the semiconductor device according to claim 1, wherein
the removing the mask material is such RIE that involves a processing selectivity for the mask material and the second interlayer insulation film.

5. The method of manufacturing the semiconductor device according to claim 1, wherein
the mask material has a high selectivity with respect to the second interlayer insulation film and the first hydrogen diffusion barrier film in etching process.

6. The method of manufacturing the semiconductor device according to claim 1, wherein
the mask material is a silicon nitride (SiN) film.

7. The method of manufacturing the semiconductor device according to claim 1, comprising:
forming the second contact as well as a wiring through damascene process.

8. The method of manufacturing the semiconductor device according to claim 1, wherein
the mask material is formed via a second hydrogen diffusion barrier film.

9. The method of manufacturing the semiconductor device according to claim 1, wherein
the mask material is formed via a second hydrogen diffusion barrier film and the second hydrogen diffusion barrier film is removed together with the mask material.

10. The method of manufacturing the semiconductor device according to claim 1, wherein
the conductive material is deposited through any of MOCVD, sputtering, plating, or sputter-reflow to form a second contact.
